(19) United States
(12) Patent Application Publication
(10) Pub. No.: US 2026/0215045 A1
(43) Pub. Date: Jul. 23, 2026

(54) POLARIZED LIGHT SOURCES FOR LCOS APPLICATIONS

(71) Applicant: Lumileds LLC, San Jose, CA (US)

(72) Inventors: Hisashi Masui, Newark, CA (US); Brendan Jude Moran, San Jose, CA (US); Oleg Borisovich Shchekin, San Francisco, CA (US); Antonio Lopez Julia, Eindhoven (NL)

(21) Appl. No.: 19/139,036

(22) PCT Filed: Dec. 12, 2023
(86) PCT No.: PCT/US2023/083568

§ 371 Date: Jun. 13, 2025

Related U.S. Application Data
(60) Provisional application No. 63/433,083, filed on Dec. 16, 2022.

(51) Int. Cl. H10H 20/856; F21V 7/00; F21Y 115/10; H10H 20/01; H10H 20/819; H10H 20/841; H10H 20/85

(52) U.S. Cl. CPC H10H 20/856; F21V 7/0025; F21V 7/0066; H10H 20/0363; H10H 20/819; H10H 20/841; H10H 20/8508; F21Y 2115/10

(57) ABSTRACT

An illumination device is provided in which polarized light is waveguided to sidewalls of a light emitting diode (LED) chip. The LED chip has a poly gonal shape to increase internal reflection to enhance light emission efficiency from the exit surface and to enlarge an area of the exit surface and reduce internal light absorption. Reflective material is disposed on surfaces other than the sidewalls. At least one reflector specularly reflects the polarized light from at least one of the sidewalls towards a common direction. Fins etched in a semiconductor stack allow the light to exit a top of the fins. A reflective material may be provided on the semiconductor stack adjacent to the fins.

### PRIORITY CLAIM

This application claims the benefit of priority to U.S. Provisional Patent Application Ser. No. 63/433,083, filed Dec. 16, 2022, which is incorporated herein by reference in its entirety.

### FIELD OF THE DISCLOSURE

The present disclosure relates to liquid crystal on silicon (LCOS) applications. In particular, embodiments are directed to polarized light sources in LCOS applications.

### BACKGROUND OF THE DISCLOSURE

There is ongoing effort to improve light engines. In particular, it is desirable to improve light efficiency in LCOS applications.

### BRIEF DESCRIPTION OF THE DRAWINGS

FIG. 1 shows an illumination apparatus, in accordance with some examples.

FIG. 2 illustrates a side view of a first embodiment of polarized light emission, in accordance with some examples.

FIG. 3 illustrates a perspective view of a second embodiment of polarized light emission, in accordance with some examples.

FIG. 4 illustrates a side view of a third embodiment of polarized light emission, in accordance with some examples.

FIG. 5A illustrates a side view of a fourth embodiment of polarized light emission, in accordance with some examples.

FIG. 5B illustrates a perspective view of the embodiment of FIG. 5A, in accordance with some examples.

FIG. 6 illustrates a perspective view of a fifth embodiment of polarized light emission, in accordance with some examples.

FIG. 7 illustrates a perspective view of a sixth embodiment of polarized light emission, in accordance with some examples.

FIG. 8 illustrates a perspective view of a seventh embodiment of polarized light emission, in accordance with some examples.

FIG. 9 illustrates a perspective view of an eighth embodiment of polarized light emission, in accordance with some examples.

FIG. 10 illustrates a perspective view of a ninth embodiment of polarized light emission, in accordance with some examples.

FIG. 11 illustrates a perspective view of a tenth embodiment of polarized light emission, in accordance with some examples.

FIG. 12 illustrates an example of an electronic device in accordance with some embodiments.

FIG. 13 illustrates an example lighting system, according to some embodiments.

FIG. 14 shows a block diagram of an example of a system, according to some embodiments.

FIG. 15 illustrates an example hardware arrangement for implementing the above disclosed subject matter, according to some embodiments.

FIG. 16 illustrates an example method of fabricating an LED device, according to some embodiments.

FIG. 17A illustrates a side view of an eleventh embodiment of polarized light emission, in accordance with some examples.

FIG. 17B illustrates a top view of the embodiment of FIG. 17A, in accordance with some examples.

FIG. 17C illustrates a perspective view of the embodiment of FIG. 17A, in accordance with some examples.

### DETAILED DESCRIPTION

An illumination device and method of fabricating an illumination device are provided. In the illumination device, polarized light is waveguided to an exit surface of a LED chip. The exit surface may include one or more sidewalls of the LED chip. The LED chip has a polygonal shape, such as, for example, a rectangular shape or a triangular shape. Reflective material is disposed on surfaces other than the exit surface. At least one reflector external to the LED chip specularly reflects the polarized light from at least one of the exit surface towards a common direction. Fins may be etched in a semiconductor stack of the LED chip to allow the light to exit a top of the fins.

A reflective material may coat the semiconductor stack adjacent to the fins. An LED chip may be particularly (although not exclusively) desirable as a backlight in LCOS applications, in which increased backlight brightness may be useful.

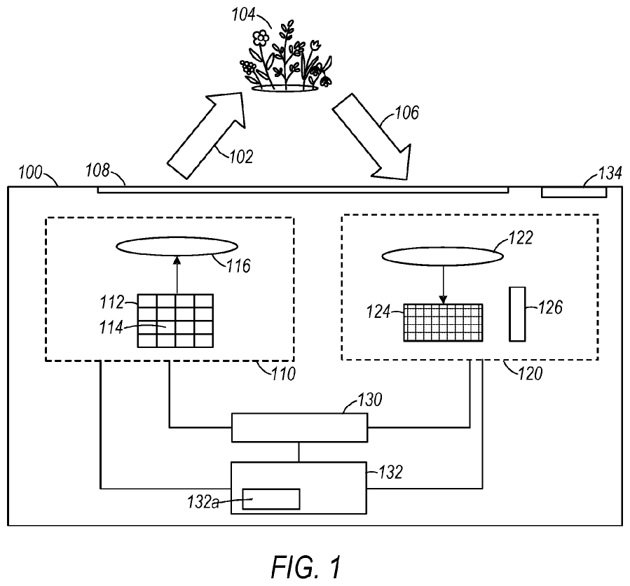

FIG. 1 shows an illumination apparatus 100, in accordance with some examples. The illumination apparatus 100 may be, for example, a smart phone or standalone camera that contains an adaptive LED light source. The illumination apparatus 100 may include both a light source 110 and a camera 120. The camera 120 may capture an image of a scene 104 during an exposure duration of the camera 120, whether or not the scene 104 is illuminated by the light source 110. A processor 130 may be used to control various functions of the light source 110 and the camera 120, including whether or not a shutter is open in an opening 108 of a housing of the illumination apparatus 100.

The opening 108 may be a single opening as shown in FIG. 1 or may include multiple separate openings. Similarly, the shutter may be a single shutter that covers both the light source 110 and the camera 120 or may include multiple separate shutters that covers only one of the light source 110 or the camera 120 and are individually controllable by the processor 130.

The illumination apparatus 100 may include one or more LED arrays 112. Each of the one or more LED arrays 112 may include a plurality of LEDs 114 that may produce light during at least a portion of the exposure duration of the camera 120. Each of the one or more LED arrays 112 may contain segmented LEDs 114 in which the LEDs 114 are divided into a grid of light emitting areas (the LEDs 114) and non-light emitting areas (between the LEDs 114). In some embodiments, the effect of the non-light emitting areas on the image captured using the one or more LED arrays 112 may be compensated for by moving the one or more LED arrays 112 and/or at least one lens 116 using one or more actuators during the exposure duration of the scene 104 to shift the LEDs 114 slightly to illuminate the areas of the scene 104 that would be subject to the non-light emitting areas.

Each of the LEDs 114 may be formed using one or more inorganic semiconductor materials (e.g., binary compounds such as gallium arsenide (GaAs) or gallium nitride (GaN), ternary compounds such as aluminum gallium arsenide (AlGaAs), quaternary compounds such as indium gallium phosphide (InGaAsP)), or other suitable materials. The LEDs 114 are typically either III-V materials (defined by columns of the Periodic Table) or II-VI materials. Each of the LEDs 114 may emit light in the visible spectrum (about 400 nm to about 780 nm) or may also emit light in the infrared spectrum (above about 780 nm). In some embodiments, one or more other layers, such as a phosphor layer may be disposed on each of the one or more LED arrays 112 to convert the light from the LEDs 114 into white (or another color) light. LEDs 114 in a particular LED array 112 that emit light in the infrared spectrum may be, for example, interspersed with LEDs 114 may emit light in the visible spectrum, or each type of LED (visible emitter/infrared emitter) may be disposed on different sections of the particular LED array 112. Alternatively, each LED array 112 may only emit light in either the visible spectrum or the infrared spectrum; separate (one or more) LED arrays may be used to emit light in the infrared spectrum, each of the individual LED array 112, LEDs 114 and/or LED segments controllable by the processor 130.

Each of the one or more LED arrays 112 may be, for example, micro-LED array, the latter of which includes thousands to millions of microscopic LEDs 114 that may emit light and that may be individually controlled or controlled in groups of pixels (e.g., 5×5 groups of pixels). MicroLEDs are relatively small (e.g., <0.01 mm on a side) compared to typical LEDs and may provide monochromatic or multi-chromatic light, typically red, green, or blue using inorganic semiconductor material such as that indicated above.

The light source 110 may include at least one lens 116 and/or other optical elements such as reflectors. The lens 116 and/or other optical elements may direct the light emitted by the one or more LED arrays 112 toward the scene 104 as illumination 102.

The camera 120 may sense light at least the wavelength or wavelengths emitted by the one or more LED arrays 112. Similar to the light source 110, the camera 120 may include optics (e.g., at least one camera lens 122) that are able to collect reflected light 106 of the illumination 102 that is reflected from and/or emitted by the scene 104. The camera lens 122 may direct the reflected light 106 onto a multi-pixel sensor 124 (also referred to as a light sensor) to form an image of the scene 104 on the multi-pixel sensor 124.

The processor 130 may receive a data signal that represents the image of the scene 104. The processor 130 may additionally control and drive the LEDs 114 in the one or more LED arrays 112 via one or more drivers 132. For example, the processor 130 may optionally control one or more LEDs 114 in the one or more LED arrays 112 independent of another one or more LEDs 114 in the one or more LED arrays 112, so as to illuminate the scene in a specified manner.

In addition, one or more detectors 126 may be incorporated in the camera 120. In other embodiments, instead of being incorporated in the camera 120, the one or more detectors 126 may be incorporated in one or more different areas, such as the light source 110 or elsewhere close to the camera 120. The one or more detectors 126 may include multiple different sensors to sense visible and/or infrared light (e.g., from the scene 104), and may further sense the ambient light and/or variations/flicker in the ambient light in addition to reception of the reflected light from the LEDs 114. The multi-pixel sensor 124 of the camera 120 may be of higher resolution than the sensors of the one or more detectors 126 to obtain an image of the scene with a desired resolution. The sensors of the one or more detectors 126 may have one or more segments (that are able to sense the same wavelength/range of wavelengths or different wavelength/range of wavelengths), similar to the LED arrays 112. In some embodiments, if multiple detectors are used, one or more of the detectors may detect visible wavelengths and one or more of the detectors may detect infrared wavelengths; like the one or more LED arrays 112, the one or more detectors 126 may be individually controllable by the processor 130.

In some embodiments, instead of, or in addition to, being provided in the camera 120, one or more of the sensors of the one or more detectors 126 may be provided in the light source 110. In some embodiments, the light source 110 and the camera 120 may be integrated in a single module, while in other embodiments, the light source 110 and the camera 120 may be separate modules that are disposed on a PCB. In other embodiments, the light source 110 and the camera 120 may be attached to different PCBs—for example, as the camera 120 may be thicker than the light source 110, which may result in design issues if the light source 110 and the camera 120 are attached to the same PCB. In the latter embodiment, multiple openings may be present in the housing at least one of which may be eliminated with the use of an integrated light source 110 and camera 120.

The LEDs 114 may be driven using a direct current (DC) driver or pulse width modulation (PWM). Using DC driving may encounter color differences if the segmented one or more LED arrays 112 is driven at different current densities, while PWM driving may generate artifacts due to ambient lighting conditions. The flicker sensor, if present, may sense the variation of artificial lighting at the wall current frequency or electronic ballasts frequencies (e.g., 50 Hz or 60 Hz or an integral multiple thereof), in addition to the phase of the flicker. The camera sensor is then tuned to an integration time of an integral multiple of the time period (1/f) or triggered at the phase where the illumination changes most slowly (minimum or maximum intensity, with the maximum intensity preferred for signal-to-noise ratio considerations). The LEDs 114 may be driven using a PWM whose phase shift varies between LEDs 114 to reduce potential current surge issues. As shown, one or more drivers 132 may be used to drive the LEDs 114 in the one or more LED arrays 112, as well as other components, such as the actuators.

The illumination apparatus 100 may also include an input device 134, for example, a user-activated input device such as a button that is depressed to take a picture. The light source 110 and camera 120 may be disposed in a single housing.

As above, the light source 110 of FIG. 1 may be an adaptive flash that contains individually addressable LED segments to allow selective illumination of the scene 104. For array sizes larger than 3×3 matrices, the LED segments may be combined with an integrated driver to allow the function of individual addressability and obtain the small form factor desired for mobile devices without creating issues in layout of the semiconductor layers used to create the integrated devices. LEDs (or microLEDs) can be used in the illumination apparatus 100 shown in FIG. 1 to form different types of displays, LED matrices and light engines including automotive adaptive headlights, augmented-, virtual-, mixed-reality (AR/VR/MR) headsets, smart glasses and displays for mobile phones, smart watches, monitors and TVs. The individual LED pixels in these architectures may have an area of few square millimeters down to few square micrometers depending on the matrix or display size and pixel-per-inch requirements.

In some applications, such as AR/VR devices, LCOS may be a main display engine. The light source may be polarized to be high efficiency. Common light sources include RGB LED discrete chips prepared in low- or mid-power packages in which light emission is unpolarized. In such LCOS light engines, a polarizer or reflection/refraction optics may be used to polarize the emitted light. However, optical losses in such cases may be as high as 50%. Therefore, the use of polarized light sources in a LCOS light engine has the potential to improve the emission efficiency as a whole.

LED chips may be fabricated using various epitaxial processes. In particular, LEDs may be formed by combining n- and p-type semiconductors (e.g., III-V semiconductors) on a substrate (wafer) of sapphire aluminum oxide (Al₂O₃) or silicon carbide (SiC), among others. Various layers may be deposited and processed on the substrate during fabrication of the LED. The surface of the substrate may be pretreated to anneal, etch, polish, etc. the surface prior to deposition of the various layers.

In general, the various LED layers of an LED structure may be fabricated using epitaxial semiconductor deposition (e.g., by metal organic chemical vapor deposition) to deposit one or more semiconductor layers, metal deposition (e.g., by sputtering), oxide growth, as well as etching, liftoff, and cleaning, among other operations. LEDs formed on the substrate may be separated, e.g., by cleaving the wafer. In some embodiments, the substrate may be removed from the LED structure after fabrication. The LED structure may be connected to contacts on a backplane via metal bonding such as via wire or ball bonding to form the LED chip. The backplane may be a printed circuit board or wafer containing integrated circuits (ICs), such as a CMOS IC wafer. The semiconductor deposition operations may be used to create an LED with an active region in which electron-hole recombination occurs and the light from the LED is generated. The active region may be, for example, one or more quantum wells. Metal contacts may be used to provide current to the n- and p-type semiconductors from the ICs (such as drivers) of the backplane on which the LED is disposed.

While in some cases light may be provided from an emission surface of the LED chip normal to the epitaxial growth direction, in other cases light may be directed to be provided from a sidewall of the LED chip. Due to the nature of waveguiding in a planar epitaxial structure light emission from the sidewall of an LED chip may be inherently polarized. Thus, when an LED chip is mounted sideways in a light engine such that emitted light from a sidewall of the LED chip is introduced to an LCOS unit, the emitted light may be polarized inherently without the use of a polarizer. In this case, the LED chip geometry may be fabricated to enhance polarization and/or efficiency.

The shape of an LED chip may be a shape other than substantially a square, such as being substantially rectangular or strip-shaped to enlarge the light emitting sidewall and to reduce internal light absorption. Alternatively, the LED chip may have a substantially triangular or frustoconical shape so that internal reflection of the LED chip may contribute to enhance light emission efficiency from a light emitting sidewall. External optics (e.g., a set of specular reflectors) may be constructed around an LED chip to maintain the polarization and to enhance efficiency.

Other embodiments may include an ensemble of parallel epilayer fins created by a deeply-trenched epilayer. This case, top light emission may also be at least partially linearly polarized due to waveguiding by the fins. As epilayers of the semiconductor stack are typically about 5 microns thick, the sizes of the fins may be in the range of microns to provide sufficient waveguide effects. To make the use of the epitaxial layer material more effective (meaning, maintaining the active region areas from etching away), in some aspects thin-film flip-chip (TFFC)-based structures may be created. In TFFC-based structures, a deep trench is fabricated from the n-epilayer side to a region adjacent to the active region, and the trenched surfaces may be coated with a reflector in order to minimize stray light.

In various embodiments, light from a sidewall may be introduced to the external optical component (e.g., a lens) of a LCOS display unit, where other faces of the LED chip may be covered with a coating to eliminate unintended stray light from entering the LED chip. The coating may be a single layer reflective coating, such as a metal, or a multilayer dielectric stack in which the dielectric constants and thicknesses of the layers forming the dielectric stack are selected to produce reflectivity at the wavelength of LED emission. In either case, the reflectivity may be greater than about 95% at the wavelength of LED emission.

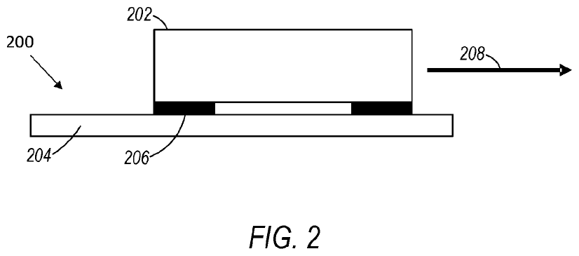

FIG. 2 illustrates a side view of a first embodiment of polarized light emission, in accordance with some examples. Other components may be present in the apparatus 200 shown in FIG. 2, but are not shown for convenience. The apparatus 200 includes a Chip Scale Package (CSP) LED chip 202 connected to a submount 204 via direct connection, such as flip chip bonds 206 (instead of an indirect connection, such as wirebonds). The submount 204 may be, for example, a PCB. The CSP LED chip 202 may be directly applied to the submount 204 reducing the heat flow path and the thermal resistance compared to a surface mount device, which may instead use wirebonds for connection to a submount.

As indicated above, the use of the CSP LED chip 202 to emit polarized light emission 208 sideways (from a sidewall) to an LCOS without the use of external optics. Note that the apparatus 200 (and other apparatuses disclosed herein) is not limited to an RGB combination for LCOS applications, other combinations of colors may be provided from the LED chip 202, as may a single color. The size of a typical CSP LED chip 202 may be, for a square size, about 0.5 mm/side, although other sizes may be used depending on the application. The CSP LED chip 202 may contain the substrate on which the epitaxial layers have been grown (e.g., sapphire), only the epitaxial layers if the substrate has been lifted off and not replaced, or another substrate (such as GaN or SiC) if the original (sapphire) substrate has been lifted off and replaced with the other substrate.

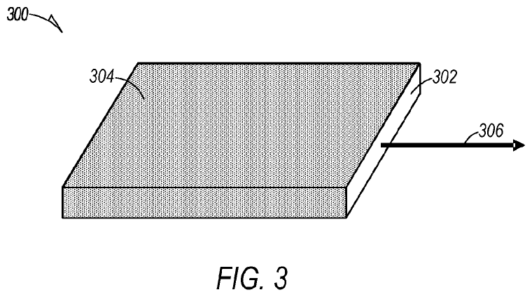

FIG. 3 illustrates a perspective view of a second embodiment of polarized light emission, in accordance with some examples. Other components may be present in the apparatus 300 shown in FIG. 3, but are not shown for convenience. The apparatus 300 includes a CSP LED chip 302 that emits polarized light emission 306 sideways to an LCOS.

At least one face of the CSP LED chip 302 may be covered with a reflective material 304. The reflective material 304 may be, for example, a metal such as aluminum (Al), silver (Ag), or gold (Au), or a multilayer structure, such as a distributed Bragg reflector (DBR) or dichroic mirror. At least one sidewall of the CSP LED chip 302 may be left open for light emission, as shown. As above, the CSP LED chip 302 may be formed in any of a number of shapes, including substantially cubic, rectangular, triangular and other polygonal shapes. The reflective material 304 may be disposed on the substrate on which the epitaxial layers have been grown, on the epitaxial layers if the substrate has been lifted off and not replaced, or another substrate (such as GaN or SiC) if the original (sapphire) substrate has been lifted off and replaced with the other substrate. The reflective material 304 may be applied to surfaces that are not used for light emission.

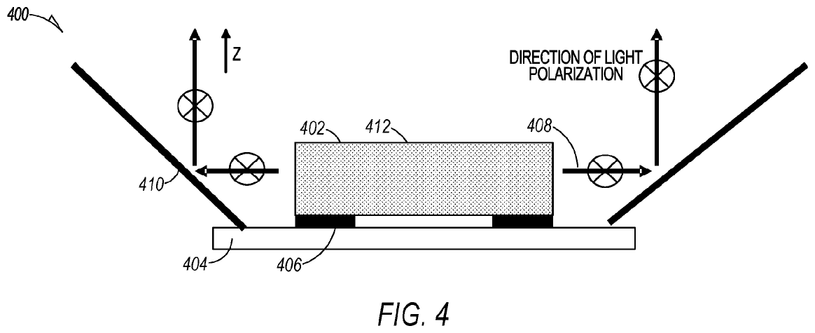

In addition to polarization, external components of the LED chip may be used to enhance efficiency and redirect the light. FIG. 4 illustrates a side view of a third embodiment of polarized light emission, in accordance with some examples. Other components may be present in the apparatus 400 shown in FIG. 4, but are not shown for convenience. The apparatus 400 includes a CSP LED chip 402 that emits polarized light emission 408 from sidewalls of the CSP LED chip 402. The CSP LED chip 402 may be directly applied to a submount 404 via flip chip bonds 406. As shown, external optics, such as specular reflectors 410, may be used to redirect the light to an LCOS disposed above the CSP LED chip 402 (i.e., in the z direction as shown in FIG. 4, substantially normal to a top surface of the CSP LED chip 402 or, alternatively, substantially parallel to surfaces of the opposing sidewalls as shown in FIG. 4). The specular reflectors 410 may maintain the polarization of the polarized light emission 408, the direction of which is shown in FIG. 4.

In some embodiments, one or more reflective coatings 412 may be applied to other (non-sidewall) faces of the CSP LED chip 402 to eliminate stray light and counteract polarization components from the other faces. In some embodiments, only the opposing sidewalls may remain uncovered by the reflective coating 412 to avoid mixing (and thus neutralizing) the polarizations. In such embodiments as shown herein, the CSP LED chip 402 may have an overall substantial rectangular or square shape, for example.

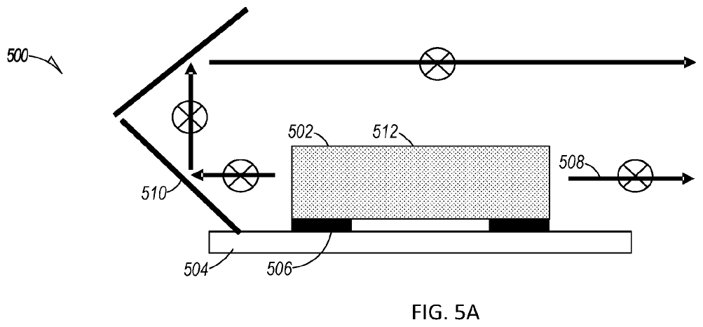

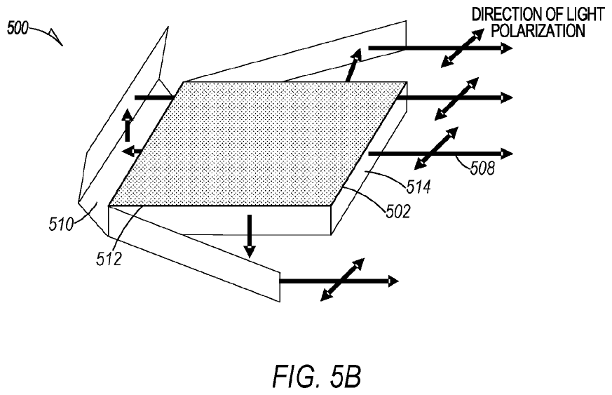

FIG. 5A illustrates a side view of a fourth embodiment of polarized light emission, in accordance with some examples. FIG. 5B illustrates a perspective view of the embodiment of FIG. 5A, in accordance with some examples. Other components may be present in the apparatus 500 shown in FIGS. 5A and 5B, but are not shown for convenience. The apparatus 500 includes a CSP LED chip 502 that emits polarized light emission 508 sideways. The CSP LED chip 502 may be directly applied to a submount 504 via flip chip bonds 506. As shown, external optics, such as specular reflectors 510, may be used to redirect the light to an LCOS disposed at one side of the CSP LED chip 502 (as shown in FIG. 5A to the right of the CSP LED chip 502). The specular reflectors 510 may maintain the polarization of the polarized light emission 508, surrounding the CSP LED chip 502 to reflect light from each of the sidewalls other than one of the sidewalls 514 so that the reflected light is in substantially the same direction as light emitted from the one sidewall 514 (e.g., within a few degrees). One or more reflective coatings 512 may be applied to other (non-sidewall) faces of the CSP LED chip 502 to eliminate stray light and counteract polarization components from the non-sidewall faces. As shown in FIGS. 5A and 5B, the direction of light polarization, which is substantially parallel to the underlying ground plane (not shown), is maintained.

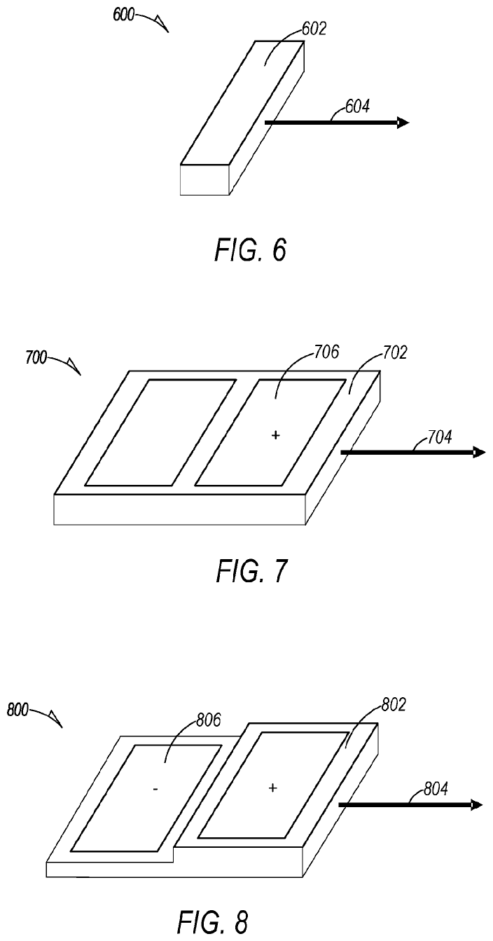

As above, the CSP LED chip may be formed to have various geometries. FIG. 6 illustrates a perspective view of a fifth embodiment of polarized light emission, in accordance with some examples. Other components may be present in the apparatus 600 shown in FIG. 6, but are not shown for convenience. The apparatus 600 includes a CSP LED chip 602 that emits polarized light emission 604 from a sidewall. As shown, the CSP LED chip 602 may be substantially rectangular to reduce internal light loss. One or more reflective coatings may be applied to other (non-sidewall) faces of the CSP LED chip 602 as described herein.

FIG. 7 illustrates a perspective view of a sixth embodiment of polarized light emission, in accordance with some examples. Other components may be present in the apparatus 700 shown in FIG. 7, but are not shown for convenience. The apparatus 700 includes a CSP LED chip 702 that emits polarized light emission 704 from a sidewall. One or more reflective coatings may be applied to other (non-sidewall) faces of the CSP LED chip 702. In the embodiment of FIG. 7, instead of direct contact (e.g., flip chip or ball bonding) for both contacts, a contact pad 706 may be disposed on the n-type semiconductor layer; a wirebond may be attached to the contact pad 706 while direct contact may be made to the p-type semiconductor layer as in the embodiments above (i.e., the negative contact may be at the bottom of the CSP LED chip 702). As shown, the CSP LED chip 702 may be substantially rectangular, but only part of the epilayer may be used for waveguiding. The active layer can be absorptive; thus only part of the active region may be used to generate light, with the remaining portion of the CSP LED chip 702 coated with the reflective material.

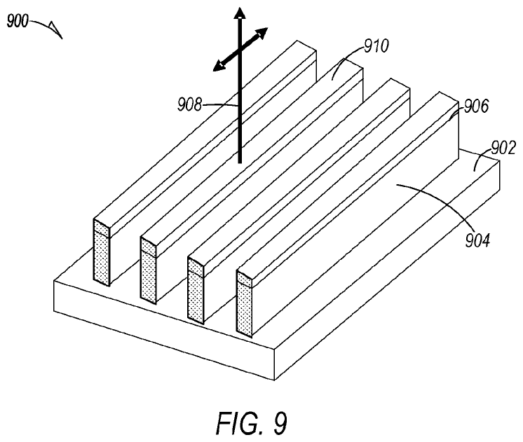

FIG. 8 illustrates a perspective view of a seventh embodiment of polarized light emission, in accordance with some examples. Other components may be present in the apparatus 800 shown in FIG. 8, but are not shown for convenience. The apparatus 800 includes a CSP LED chip 802 that emits polarized light emission 804 from a sidewall. One or more reflective coatings may be applied to other (non-sidewall) faces of the CSP LED chip 802. As shown, a portion of the active region of the CSP LED chip 802 may be removed. In FIG. 8, both positive and negative contact pads 806 may be disposed on the different semiconductor layers to allow electrical contact (wirebonding for example) to each semiconductor layer. As shown, the portion of the active layer not used may be etched and removed to reduce absorption; the negative contact of the contact pads 806 may then be deposited on the remaining portion as illustrated.

As above, other embodiments may be used in which fins provide the polarized light. FIG. 9 illustrates a perspective view of an eighth embodiment of polarized light emission, in accordance with some examples. Other components may be present in the CSP LED chip 900 shown in FIG. 9, but are not shown for convenience. The CSP LED chip 900 may emit polarized light emission 908 from a top surface 910 of each of a plurality of fins 904 disposed on a (sapphire) substrate 902. As shown, the fins 904 are isolated from each other (e.g., air gapped). An active region 906 may be disposed in each fin 904. The fins 904 may be substantially parallel created by etching trenches in the epilayers. Thus, top light emission may also be at least partially linearly polarized due to waveguiding by the fins 904. The fins 904 may be microns tall from the planar surface of the substrate 902 on which the fins 904 are disposed to provide the waveguide. The fins 904 may be trenched surfaces that are coated with the reflective material to minimize stray light emission. In some embodiments, the thickness of the fins 904 may be about 10 μm to about 100 μm, the gap between adjacent fins 904 may be in the same range, and/or the depth of the fins 904 may be about 1 μm to about 5 μm.

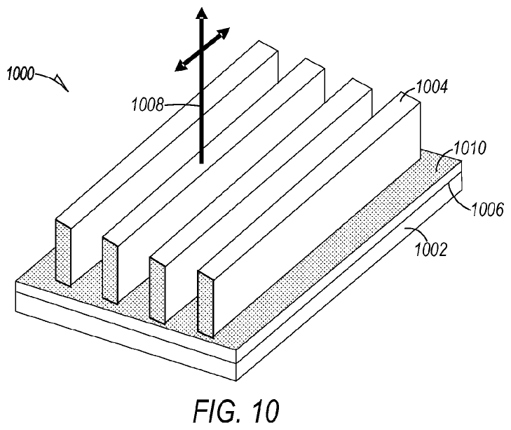

FIG. 10 illustrates a perspective view of a ninth embodiment of polarized light emission, in accordance with some examples. Other components may be present in the CSP LED chip 1000 shown in FIG. 10, but are not shown for convenience. The CSP LED chip 1000 includes a semiconductor stack 1002 that emits polarized light emission 1008 from a top surface of each of a plurality of fins 1004. An active region 1006 may be disposed in the bulk of the semiconductor stack 1002 instead of in the fins 1004. The fins 1004 may be substantially parallel created by etching trenches in the epilayers. Thus, top light emission may also be at least partially linearly polarized due to waveguiding by the fins 1004. The fins 1004 may be microns tall from the planar surface of the semiconductor stack 1002 on which the fins 1004 are disposed to provide the waveguide. The trenched surfaces may be coated with one or more reflective layers in order to minimize stray light. An internal reflective coating 1010 may be disposed on the planar surface of the semiconductor stack 1002. The reflective coating 1010 may be, for example, titanium tungsten on silver on the epitaxial layer forming the planar surface of the semiconductor stack 1002. Note that, as all embodiments, the p-type semiconductor of the semiconductor stack 1002 may be attached to a conducting submount. The dimensions of the fins 1004 may be similar to those in FIG. 9.

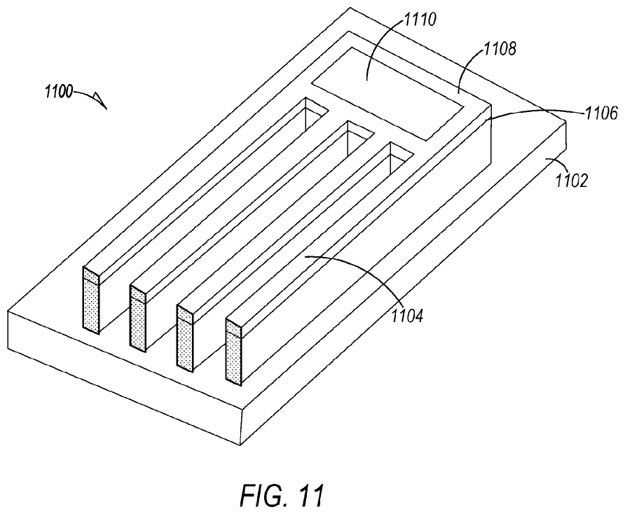

FIG. 11 illustrates a perspective view of a tenth embodiment of polarized light emission, in accordance with some examples. Other components may be present in the CSP LED chip 1100 shown in FIG. 11, but are not shown for convenience. The CSP LED chip 1100 may emit polarized light emission from a top surface of each of a plurality of fins 1104 disposed on a substrate 1102. An active region 1106 may be disposed in each fin 1104. The fins 1104 may be substantially parallel created by etching trenches in the epilayers. Thus, top light emission may also be at least partially linearly polarized due to waveguiding by the fins 1104. The fins 1104 may be microns tall from the planar surface of the substrate 1102 on which the fins 1104 are disposed to provide the waveguide. The trenched surfaces may be coated with one or more reflective layers in order to minimize stray light. As shown in FIG. 11, instead of being isolated from each other, the fins 1104 may be connected at one end 1108. In this case, a bond pad 1110 may be disposed on a top surface of the end 1108. The bond pad 1110 may be formed from a metal, such as Au, or a combination of metals to allow contact to be made to at least the underlying n-type semiconductor. The dimensions of the fins 1104 may be the same as in FIG. 9.

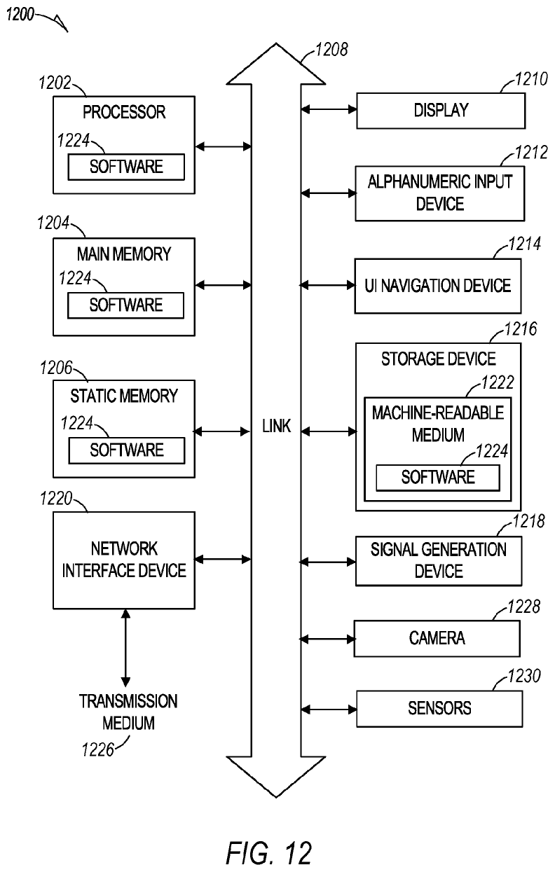

FIG. 12 illustrates an example of an electronic device in accordance with some embodiments. The electronic device 1200 may be a mobile device such as a laptop computer (PC), a tablet PC, or a smart phone, for example, or a dedicated electronic apparatus, such as a camera, for example. Various elements may be provided on the PCB indicated above. Examples, as described herein, may include, or may operate on, logic or a number of components, modules, or mechanisms. Modules and components are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” (and “component”) is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

The mobile device 1200 may include a hardware processor (or equivalently processing circuitry) 1202 (e.g., a central processing unit (CPU), a GPU, a hardware processor core, or any combination thereof), a main memory 1204 and a static memory 1206, some or all of which may communicate with each other via an interlink (e.g., bus) 1208. The main memory 1204 may contain any or all of removable storage and non-removable storage, volatile memory or non-volatile memory. The mobile device 1200 may further include a display 1210 such as a video display, an alphanumeric input device 1212 (e.g., a keyboard), and a user interface (UI) navigation device 1214 (e.g., a mouse). In an example, the display 1210, input device 1212 and UI navigation device 1214 may be a touch screen display. The mobile device 1200 may additionally include a storage device (e.g., drive unit) 1216, a signal generation device 1218 (e.g., a speaker), a network interface device 1220, one or more cameras 1228, and one or more sensors 1230, such as a global positioning system (GPS) sensor, compass, accelerometer, or other sensor such as those described herein. The mobile device 1200 may further include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 1216 may include a non-transitory machine readable medium 1222 (hereinafter simply referred to as machine readable medium) on which is stored one or more sets of data structures or instructions 1224 (e.g., software) embodying or utilized by any one or more of the techniques or functions described herein. The non-transitory machine readable medium 1222 is a tangible medium. A storage device 1216 that includes the non-transitory machine-readable medium should not be construed as that either the device or the machine-readable medium is itself incapable of having physical movement. The instructions 1224 may also reside, completely or at least partially, within the main memory 1204, within static memory 1206, and/or within the hardware processor 1202 during execution thereof by the mobile device 1200. While the machine readable medium 1222 is illustrated as a single medium, the term “machine readable medium” may include a single medium or multiple media (e.g., a centralized or distributed database, and/or associated caches and servers) configured to store the one or more instructions 1224.

The term “machine readable medium” may include any medium that is capable of storing, encoding, or carrying instructions for execution by the mobile device 1200 and that cause the mobile device 1200 to perform any one or more of the techniques of the present disclosure, or that is capable of storing, encoding or carrying data structures used by or associated with such instructions. Non-limiting machine-readable medium examples may include solid-state memories, and optical and magnetic media. Specific examples of machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks.

The instructions 1224 may further be transmitted or received over a communications network using a transmission medium 1226 via the network interface device 1220 utilizing any one of a number of wireless local area network (WLAN) transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks. Communications over the networks may include one or more different protocols, such as Institute of Electrical and Electronics Engineers (IEEE) 802.11 family of standards known as Wi-Fi, IEEE 802.16 family of standards known as WiMax, IEEE 802.15.4 family of standards, a Long Term Evolution (LTE) family of standards, a Universal Mobile Telecommunications System (UMTS) family of standards, peer-to-peer (P2P) networks, a next generation (NG)/5^{th} generation (5G) standards among others. In an example, the network interface device 1220 may include one or more physical jacks (e.g., Ethernet, coaxial, or phone jacks) or one or more antennas to connect to the transmission medium 1226.

Note that the term “circuitry” as used herein refers to, is part of, or includes hardware components such as an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” or “processor” as used herein thus refers to, is part of, or includes circuitry capable of sequentially and automatically carrying out a sequence of arithmetic or logical operations, or recording, storing, and/or transferring digital data. The term “processor circuitry” or “processor” may refer to one or more application processors, one or more baseband processors, a physical central processing unit (CPU), a single- or multi-core processor, and/or any other device capable of executing or otherwise operating computer-executable instructions, such as program code, software modules, and/or functional processes.

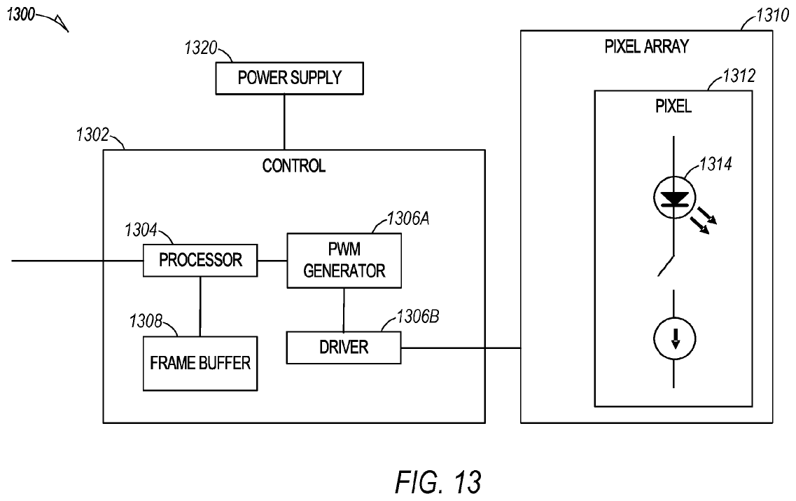

FIG. 13 illustrates an example lighting system, according to some embodiments. As above, some of the elements shown in the lighting system 1300 may not be present, while other additional elements may be disposed in the lighting system 1300. The lighting system 1300 may provide lighting based on an image captured as described in FIG. 1, or may be independently generated based on stored information. For example, the lighting system 1300 may include a controller 1302 that controls display of an image using a pixel array 1310 that contains multiple individual pixels 1312.

In some embodiments, some or all of the components described as the controller 1302 may be disposed on a backplane such as, for example, a compound metal oxide semiconductor (CMOS) backplane. The controller 1302 may be coupled to or include one or more processors 1304. The controller 1302 may receive image data and inquiries from the one or more processors 1304, if external to the controller 1302. In this case, the controller 1302 may further provide feedback to the one or more processors 1304. The one or more processors 1304 may receive image data via a digital interface and may process the image data to control a PWM generator 1306a, for example, controlling PWM duty cycles and/or turn-on times for causing the lighting system 1300 to produce the images indicated by the image data.

The controller 1302 may further include a frame buffer 1308. The frame buffer 1308 may store one or more images prior the one or more processors 1304 and store the indications for implementation by the one or more processors 1304.

The PWM generator 1306a may be controlled by the one or more processors 1304 and may produce PWM signals in accordance with the indications. The PWM generator 1306a may be connected to a driver 1306b to drive the pixel array 1310 so that the pixels 1312 provide desired intensities of light.

Each pixel 1312 may include one or more microLEDs 1314. The microLEDs 1314 may be different colors and may be controlled individually or in groups. As shown, the pixel 1312 may include, for each pixel 1312 or microLED 1314, a PWM switch, and a current source. The pixel 1312 may be driven by the driver 1306b. The PWM signal from the PWM generator 1306a may cause the PWM switch to open and close in accordance with the value of the PWM signal. The signal corresponding to the intensities of light may cause the current source to produce a current flow to cause the pixel 1312 to produce the corresponding intensities of light.

The lighting system 1300 may further include a power supply 1320. In some embodiments, the power supply 1320 may produce power for the controller 1302.

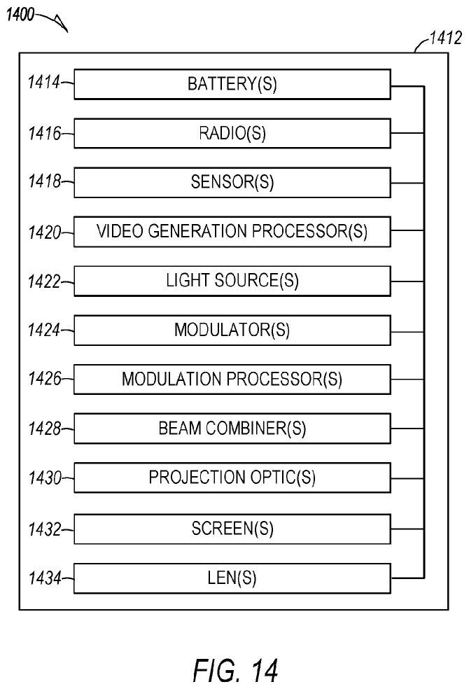

FIG. 14 shows a block diagram of an example of a system, according to some embodiments. The system 1400 may provide augmented reality (AR)/virtual reality (VR) functionality using microLEDs. The system 1400 can include a wearable housing 1412, such as a headset or goggles. The housing 1412 can mechanically support and house the elements detailed below. In some examples, one or more of the elements detailed below can be included in one or more additional housings that can be separate from the wearable housing 1412 and couplable to the wearable housing 1412 wirelessly and/or via a wired connection. For example, a separate housing can reduce the weight of wearable goggles, such as by including batteries, radios, and other elements. The housing 1412 can include one or more batteries 1414, which can electrically power any or all of the elements detailed below. The housing 1412 can include circuitry that can electrically couple to an external power supply, such as a wall outlet, to recharge the batteries 1414. The housing 1412 can include one or more radios 1416 to communicate wirelessly with a server or network via a suitable protocol, such as WiFi.

The system 1400 can include one or more sensors 1418, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 1418 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an AR system, one or more of the sensors 1418 can capture a real-time video image of the surroundings proximate a user.

The system 1400 can include one or more video generation processors 1420. The one or more video generation processors 1420 can receive scene data that represents a three-dimensional scene, such as a set of position coordinates for objects in the scene or a depth map of the scene. This data may be received from a server and/or a storage medium. The one or more video generation processors 1420 can receive one or more sensor signals from the one or more sensors 1418. In response to the scene data, which represents the surroundings, and at least one sensor signal, which represents the location and/or orientation of the user with respect to the surroundings, the one or more video generation processors 1420 can generate at least one video signal that corresponds to a view of the scene. In some examples, the one or more video generation processors 1420 can generate two video signals, one for each eye of the user, that represent a view of the scene from a point of view of the left eye and the right eye of the user, respectively. In some examples, the one or more video generation processors 1420 can generate more than two video signals and combine the video signals to provide one video signal for both eyes, two video signals for the two eyes, or other combinations.

The system 1400 can include one or more light sources 1422 that can provide light for a display of the system 1400. Suitable light sources 1422 can include the microLEDs above, for example. The one or more light sources 1422 can include light-producing elements having different colors or wavelengths. For example, a light source can include a red light-emitting diode that can emit red light, a green light-emitting diode that can emit green light, and a blue light-emitting diode that can emit blue right. The red, green, and blue light combine in specified ratios to produce any suitable color that is visually perceptible in a visible portion of the electromagnetic spectrum.

The system 1400 can include one or more modulators 1424. The modulators 1424 can be implemented in one of at least two configurations. In a first configuration, the modulators 1424 can include circuitry that can modulate the light sources 1422 directly. For example, the light sources 1422 can include an array of light-emitting diodes, and the modulators 1424 can directly modulate the electrical power, electrical voltage, and/or electrical current directed to each light-emitting diode in the array to form modulated light. The modulation can be performed in an analog manner and/or a digital manner. In some examples, the light sources 1422 can include an array of red light-emitting diodes, an array of green light-emitting diodes, and an array of blue light-emitting diodes, and the modulators 1424 can directly modulate the red light-emitting diodes, the green light-emitting diodes, and the blue light-emitting diodes to form the modulated light to produce a specified image.

In a second configuration, the modulators 1424 can include a modulation panel, such as a liquid crystal panel. The light sources 1422 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 1424 can include multiple modulation panels that can modulate different colors of light. For example, the modulators 1424 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 1424 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The system 1400 can include one or more modulation processors 1426, which can receive a video signal, such as from the one or more video generation processors 1420, and, in response, can produce an electrical modulation signal. For configurations in which the modulators 1424 directly modulate the light sources 1422, the electrical modulation signal can drive the light sources 1422. For configurations in which the modulators 1424 include a modulation panel, the electrical modulation signal can drive the modulation panel.

The system 1400 can include one or more beam splitters 1428 (and/or beam combiners), which can combine light beams of different colors to form a single multi-color beam. For configurations in which the light sources 1422 can include multiple light-emitting diodes of different colors, the system 1400 can include one or more wavelength-sensitive (e.g., dichroic) beam splitters 1428 that can combine the light of different colors to form a single multi-color beam.

The system 1400 can direct the modulated light toward the eyes of the viewer in one of at least two configurations. In a first configuration, the system 1400 can function as a projector, and can include suitable projection optics 1430 that can project the modulated light onto one or more screens 1432. The screens 1432 can be located a suitable distance from an eye of the user. The system 1400 can optionally include one or more lenses 1434 that can locate a virtual image of a screen 1432 at a suitable distance from the eye, such as a close-focus distance, such as 500 mm, 750 mm, or another suitable distance. In some examples, the system 1400 can include a single screen 1432, such that the modulated light can be directed toward both eyes of the user. In some examples, the system 1400 can include two screens 1432, such that the modulated light from each screen 1432 can be directed toward a respective eye of the user. In some examples, the system 1400 can include more than two screens 1432. In a second configuration, the system 1400 can direct the modulated light directly into one or both eyes of a viewer. For example, the projection optics 1430 can form an image on a retina of an eye of the user, or an image on each retina of the two eyes of the user.

For some configurations of AR systems, the system 1400 can include at least a partially transparent display, such that a user can view the user's surroundings through the display. For such configurations, the AR system can produce modulated light that corresponds to the augmentation of the surroundings, rather than the surroundings itself. For example, in the example of a retailer showing a chair, the AR system can direct modulated light, corresponding to the chair but not the rest of the room, toward a screen or toward an eye of a user.

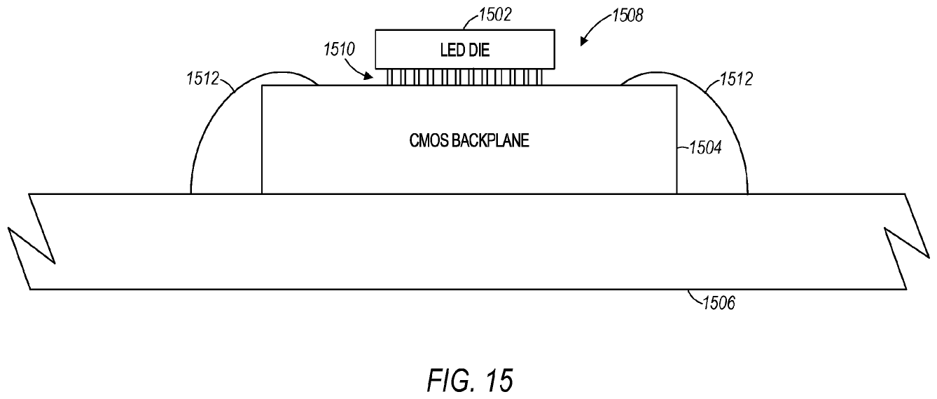

FIG. 15 illustrates an example hardware arrangement for implementing the above disclosed subject matter, according to some embodiments. In particular, the hardware arrangement 1500 may include an integrated LED 1508. The integrated LED 1508 may include an LED die 1502 that contains the microLED array(s) and a backplane, such as a CMOS backplane 1504. The LED die 1502 may be coupled to the CMOS backplane 1504 by one or more interconnects 1510, where the interconnects 1510 may provide for transmission of signals between the LED die 1502 and the CMOS backplane 1504. The interconnects 1510 may comprise one or more solder bump joints, one or more copper pillar bump joints, other types of interconnects known in the art, or some combination thereof.

The LED die 1502 may include circuitry to implement the micro-LED array. In particular, the LED die 1502 may include a plurality of micro-LEDs. The LED die 1502 may include a shared active layer and a shared substrate for the micro-LED array, and thereby the micro-LED array may be a monolithic micro-LED array. Each micro-LED of the micro-LED array may include an individual segmented active layer and/or substrate. In some embodiments, the LED die 1502 may further include switches and current sources to drive the micro-LED array. In other embodiments, the PWM switches and the current sources may be included in the CMOS backplane 1504.

The CMOS backplane 1504 may include circuitry to implement the control module and/or the LED power supply. The CMOS backplane 1504 may utilize the interconnects 1510 to provide the micro-LED array with the PWM signals and the signals for the intensity for causing the micro-LED array to produce light in accordance with the PWM signals and the intensity. Because of the relatively large number and density of connections to drive the micro-LED array compared to standard LED arrays, different embodiments may be used to electrically connect the CMOS backplane 1504 and the LED die 1502. Either the bonding pad pitch of the CMOS backplane 1504 may be the same as the pitch of bonding pads in the micro-LED array, or the bonding pad pitch of the CMOS backplane 1504 may be larger than the pitch of bonding pads in the micro-LED array.

The hardware arrangement 1500 may further include a PCB 1506. The PCB 1506 may include circuitry to implement various functionality described herein. The PCB 1506 may be coupled to the CMOS backplane 1504. For example, the PCB 1506 may be coupled to the CMOS backplane 1504 via one or more wire bonds 1512. The PCB 1506 and the CMOS backplane 1504 may exchange image data, power, and/or feedback via the coupling, among other signals.

As shown, the micro-LEDs and circuitry supporting the micro-LED array can be packaged and include a submount or printed circuit board for powering and controlling light production by the micro-LEDs. The PCB supporting the micro-LED array may include electrical vias, heat sinks, ground planes, electrical traces, and flip chip or other mounting systems. The submount or PCB may be formed of any suitable material, such as ceramic, silicon, aluminum, etc. If the submount material is conductive, an insulating layer may be formed over the substrate material, and a metal electrode pattern formed over the insulating layer for contact with the micro-LED array. The submount can act as a mechanical support, providing an electrical interface between electrodes on the micro-LED array and a power supply, and also provide heat sink functionality.

As above, a variety of applications may be supported by micro-LED arrays. Such applications may include a stand-alone applications to provide general illumination (e.g., within a room or vehicle) or to provide specific images. In addition to devices such as a luminaire, projector, mobile device, the system may be used to provide either augmented reality (AR) and virtual reality (VR)-based applications. Visualization systems, such as VR and AR systems, are becoming increasingly more common across numerous fields such as entertainment, education, medicine, and business. Various types of devices may be used to provide AR/VR to users, including headsets, glasses, and projectors. Such an AR/VR system may include components similar to those described above: the micro-LED array, a display or screen (which may include touchscreen elements), a micro-LED array controller, sensors, and a controller, among others. The AR/VR components can be disposed in a single structure, or one or more of the components shown can be mounted separately and connected via wired or wireless communication. Power and user data may be provided to the controller. The user data input can include information provided by audio instructions, haptic feedback, eye or pupil positioning, or connected keyboard, mouse, or game controller. The sensors may include cameras, depth sensors, audio sensors, accelerometers, two or three axis gyroscopes and other types of motion and/or environmental/wearer sensors that provide the user input data. Other sensors can include but are not limited to air pressure, stress sensors, temperature sensors, or any other suitable sensors for local or remote environmental monitoring. In some embodiments, the control input can include detected touch or taps, gestural input, or control based on headset or display position. As another example, based on the one or more measurement signals from one or more gyroscope or position sensors that measure translation or rotational movement, an estimated position of the AR/VR system relative to an initial position can be determined.

In some embodiments, the controller may control individual micro-LEDs or one or more micro-LED pixels (groups of micro-LEDs) to display content (AR/VR and/or non-AR/VR) to the user while controlling other micro-LEDs and sensors used in eye tracking to adjust the content displayed. Content display micro-LEDs may be designed to emit light within the visible band (approximately 400 nm to 780 nm) while micro-LEDs used for tracking may be designed to emit light in the IR band (approximately 780 nm to 2,200 nm). In some embodiments, the tracking micro-LEDs and content micro-LEDs may be simultaneously active. In some embodiments, the tracking micro-LEDs may be controlled to emit tracking light during a time period that content micro-LEDs are deactivated and are thus not displaying content to the user. The AR/VR system can incorporate optics, such as those described above, and/or an AR/VR display, for example to couple light emitted by micro-LED array onto the AR/VR display.

In some embodiments, the AR/VR controller may use data from the sensors to integrate measurement signals received from the accelerometers over time to estimate a velocity vector and integrate the velocity vector over time to determine an estimated position of a reference point for the AR/VR system. In other embodiments, the reference point used to describe the position of the AR/VR system can be based on depth sensor, camera positioning views, or optical field flow. Based on changes in position, orientation, or movement of the AR/VR system, the system controller can send images or instructions the light emitting array controller. Changes or modification the images or instructions can also be made by user data input, or automated data input.

In general, in a VR system, a display can present to a user a view of scene, such as a three-dimensional scene. The user can move within the scene, such as by repositioning the user's head or by walking. The VR system can detect the user's movement and alter the view of the scene to account for the movement. For example, as a user rotates the user's head, the system can present views of the scene that vary in view directions to match the user's gaze. In this manner, the VR system can simulate a user's presence in the three-dimensional scene. Further, a VR system can receive tactile sensory input, such as from wearable position sensors, and can optionally provide tactile feedback to the user.

In an AR system, on the other hand, the display can incorporate elements from the user's surroundings into the view of the scene. For example, the AR system can add textual captions and/or visual elements to a view of the user's surroundings. For example, a retailer can use an AR system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the AR system can position a virtual chair in a room. The user can stand in the room on a front side of the virtual chair location to view the front side of the chair. The user can move in the room to an area behind the virtual chair location to view a back side of the chair. In this manner, the AR system can add elements to a dynamic view of the user's surroundings.

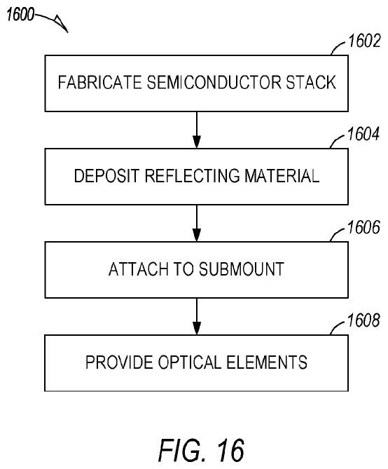

FIG. 16 illustrates an example method of fabricating an LED device, according to some embodiments. Not all of the operations may be undertaken in the method 1600, and/or additional operations may be present. The operations may occur in a different order from that indicated in FIG. 16. Examples of the resulting structures are shown in the figures herein.

At operation 1602, a semiconductor stack of the LED structure may be formed via an epitaxial process. The semiconductor stack that includes the n-type and p-type semiconductor layers, as well as the active region therebetween in which light is created through electron-hole recombination processes. In some embodiments, the fabrication of the semiconductor stack may include etching of the n-type semiconductor layer to form fins. The semiconductor stack may be formed in any of a number of geometric shapes, such as rectangular, to provide polarized light emission from one or more sidewalls of the semiconductor stack based on waveguiding within the epitaxial semiconductor layers. The semiconductor stack may be formed on a sapphire or other substrate.

After fabrication of the semiconductor stack, reflective material may be formed at operation 1604. The reflective material may include one or more reflecting layers that may be any structure that reflects wavelengths emitted by the active region. The reflective material 304 may be, for example, a metal or a multilayer structure, such as a distributed Bragg reflector (DBR) or dichroic mirror. The reflective material may be formed on one or more of the surfaces of the semiconductor stack that are not to emit the light from the active region.

The LED structure may be attached to a submount at operation 1606. The submount may be a PCB or other wafer that contains control and/or driving circuitry, for example, used to control light emission from the LED structure. Flip-chip or other bonding techniques may be used to electrically attach the LED structure to the submount.

At operation 1608, optical elements may be provided to the overall structure. The optical elements may include external reflectors and/or lenses, for example, to redirect the polarized emitted light in a predetermined direction, in some embodiments without changing the polarization.

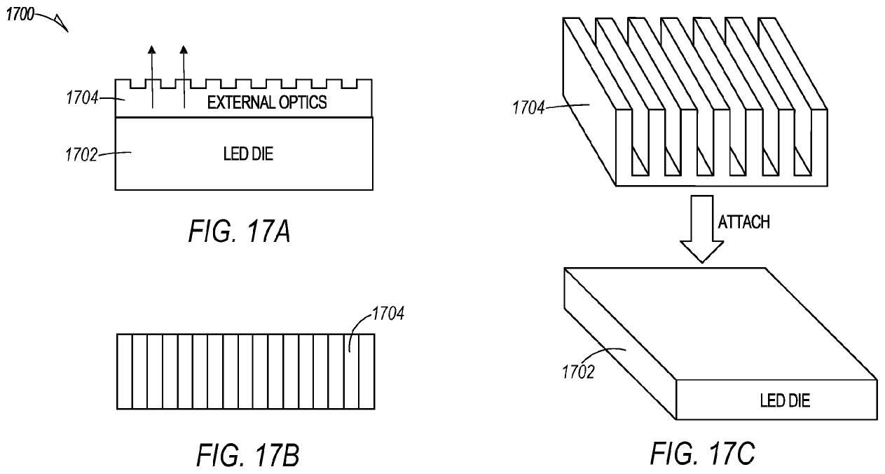

FIG. 17A illustrates a side view of an eleventh embodiment of polarized light emission, in accordance with some examples. FIG. 17B illustrates a top view of the embodiment of FIG. 17A, in accordance with some examples. FIG. 17C illustrates a perspective view of the embodiment of FIG. 17A, in accordance with some examples. As shown, the polarized light emission structure 1700 may include an LED die 1702 (semiconductor stack) configured to emit light and a grooved optic 1704 that contains regular grooves configured to provide polarization of the light emitted by the LED die 1702. The grooved optic 1704 may be formed, for example, from glass or one or more other layers that form a structure substantially transparent to the light emitted by the LED die 1702. The grooved optic 1704 may be, for example, a parallel array of fins that are substantially transparent to at least the wavelength emitted by the LED die 1702. As shown, light emitted by the LED die 1702 may become polarized by the waveguide effect of the grooved optic 1704. In some embodiments, the grooved optic 1704 may have a width of about 1 μm to about 100 μm (but smaller than the die dimension), a pitch of about 2 μm to about 200 μm (but smaller than the die dimension), and a height of about 1 μm to about 200 μm.

### EXAMPLES

Example 1 is a light-emitting diode (LED) structure comprising: an LED chip comprising a semiconductor stack that includes, an n-type semiconductor, a p-type semiconductor, and an active region sandwiched between the n-type semiconductor and the p-type semiconductor, the semiconductor stack having an exit surface from which light generated by the active region is to be waveguided to exit the semiconductor stack as polarized light; and a submount to which the LED chip is electrically coupled. The submount may be electrically coupled the LED chip via a direct connection. The polarized light may be directed towards a liquid crystal on silicon (LCOS) structure.

In Example 2, the subject matter of Example 1 includes, wherein the LED chip has a shape configured to enlarge an area of the exit surface and reduce internal light absorption.

In Example 3, the subject matter of Examples 1-2 includes, wherein the LED chip has a shape configured to increase internal reflection to enhance light emission efficiency from the exit surface.

In Example 4, the subject matter of Examples 1-3 includes, wherein the LED chip further comprises reflective material disposed on at least one surface other than the exit surface, the reflective material configured to reflect light of a wavelength of the light generated by the active region, the reflective material comprising at least one material selected from a metal and a multilayer structure.

In Example 5, the subject matter of Examples 1-4 includes, wherein: the semiconductor stack has a plurality of sidewalls from which light generated by the active region is configured to exit the semiconductor stack as polarized light, and the LED structure further comprises at least one reflector configured to specularly reflect the polarized light that has exited the semiconductor stack from at least one of the sidewalls.

In Example 6, the subject matter of Example 5 includes, wherein: the plurality of sidewalls includes a first sidewall and a second sidewall opposing the first sidewall, and the at least one reflector includes a first reflector configured to specularly reflect the polarized light that has exited the first sidewall towards a predetermined direction and a second reflector configured to specularly reflect the polarized light that has exited the second sidewall towards the predetermined direction.

In Example 7, the subject matter of Example 6 includes, wherein the predetermined direction is substantially parallel to surfaces of the opposing sidewalls.

In Example 8, the subject matter of Examples 5-7 includes, wherein: the plurality of sidewalls includes a first sidewall and a second sidewall opposing the first sidewall, the polarized light that has exited the first sidewall is configured to radiate in a predetermined direction, and the at least one reflector includes reflectors configured to specularly reflect the polarized light that has exited the second sidewall towards the predetermined direction.

In Example 9, the subject matter of Example 8 includes, wherein: the plurality of sidewalls further includes a third sidewall and a fourth sidewall opposing the third sidewall, the first sidewall and the second sidewall arranged substantially perpendicular to the third sidewall and the fourth sidewall, and the at least one reflector includes reflectors configured to specularly reflect the polarized light that has exited the third sidewall and the fourth sidewall towards the predetermined direction.

In Example 10, the subject matter of Examples 1-9 includes, wherein: the LED chip comprises a first portion in which light is to be generated and a second portion in which light is not to be generated, the second portion is laterally adjacent to and substantially planar with the first portion, and a contact pad is disposed on the first portion, the contact pad is electrically coupled with the n-type semiconductor and having dimensions for a wirebond contact.

In Example 11, the subject matter of Examples 1-10 includes, wherein: the LED chip comprises a first portion in which light is to be generated and a second portion in which light is not to be generated, the second portion is laterally adjacent to the first portion, the second portion being etched to the p-type semiconductor, a first contact pad is disposed on the first portion, the first contact pad is electrically coupled with the n-type semiconductor and having dimensions sufficient for a first wirebond contact, and a second contact pad is disposed on the second portion, the second contact pad is electrically coupled with the p-type semiconductor and having dimensions sufficient for a second wirebond contact.

In Example 12, the subject matter of Examples 1-11 includes, wherein: the semiconductor stack comprises a plurality of fins extending from a substrate, each fin contains the n-type semiconductor, the p-type semiconductor, and the active region, and light that is to be generated by the active region in each fin is configured to exit a top surface of the fin as the polarized light.

In Example 13, the subject matter of Example 12 includes, wherein each of the plurality of fins is isolated from one another.

In Example 14, the subject matter of Examples 12-13 includes, wherein: each of the plurality of fins is physically connected at one end, and a bond pad is disposed on a top of the one end to make electrical contact to the n-type semiconductor.

In Example 15, the subject matter of Examples 1-14 includes, wherein: the semiconductor stack comprises a plurality of fins extending from an underlying structure, the underlying structure includes the p-type semiconductor, the active region, and a portion of the n-type semiconductor, each fin contains a remaining portion of the n-type semiconductor, and light generated by the active region is configured to exit a top surface of the fin as polarized light.

In Example 16, the subject matter of Example 15 includes, wherein: the underlying structure further includes reflective material covering the portion of the n-type semiconductor other than locations from which the fins extend, and the reflective material is configured to reflect light of a wavelength of the light generated by the active region, the reflective material comprising at least one material selected from a metal and a multilayer structure.

Example 17 is an illumination device comprising: a light-emitting diode (LED) chip comprising a sidewall from which light generated by an active semiconductor region is waveguided to exit the LED chip as polarized light; and a submount to which the LED chip is electrically coupled, the submount comprising control circuitry to control light emission from the LED chip. The submount may be electrically coupled the LED chip via a direct connection. The polarized light may be directed towards a liquid crystal on silicon (LCOS) structure.

In Example 18, the subject matter of Example 17 includes, wherein: the LED chip has a plurality of sidewalls from which light generated by the active semiconductor region is configured to exit the LED chip as polarized light, and the illumination device further comprises at least one reflector configured to specularly reflect the polarized light that has exited the LED chip from at least one of the sidewalls.

Example 19 is a method of fabricating an illumination device, the method comprising: epitaxially growing, on a substrate, a semiconductor stack that includes, an n-type semiconductor, a p-type semiconductor, and an active region sandwiched between the n-type semiconductor and the p-type semiconductor; forming a light-emitting diode (LED) chip having an exit surface from which light generated by the active region is waveguided to exit the semiconductor stack as polarized light; and electrically coupling the LED chip to a submount to control light emission from the LED chip. The submount may be electrically coupled the LED chip via a direct connection. The polarized light may be directed towards a liquid crystal on silicon (LCOS) structure.

In Example 20, the subject matter of Example 19 includes, wherein forming the LED chip comprises shaping the LED chip to have a shape configured to enlarge an area of the exit surface and reduce internal light absorption.

In Example 21, the subject matter of Examples 19-20 includes, wherein forming the LED chip comprises shaping the LED chip to have a shape configured to increase internal reflection to enhance light emission efficiency from the exit surface.

In Example 22, the subject matter of Examples 19-21 includes, wherein forming the LED chip comprises arranging reflective material disposed on at least one surface other than the exit surface, the reflective material arranged to reflect light of a wavelength of the light generated by the active region, the reflective material comprising at least one material selected from a metal and a multilayer structure.

In Example 23, the subject matter of Examples 19-22 includes, wherein: the semiconductor stack has a plurality of sidewalls from which light generated by the active region is configured to exit the semiconductor stack as polarized light, and forming the LED chip comprises arranging at least one reflector to specularly reflect the polarized light that has exited the semiconductor stack from at least one of the sidewalls.

In Example 24, the subject matter of Example 23 includes, wherein: the plurality of sidewalls includes a first sidewall and a second sidewall opposing the first sidewall, and the at least one reflector includes a first reflector arranged to specularly reflect the polarized light that has exited the first sidewall towards a predetermined direction and a second reflector arranged to specularly reflect the polarized light that has exited the second sidewall towards the predetermined direction.

In Example 25, the subject matter of Example 24 includes, wherein the predetermined direction is substantially parallel to surfaces of the opposing sidewalls.

In Example 26, the subject matter of Examples 23-25 includes, wherein: the plurality of sidewalls includes a first sidewall and a second sidewall opposing the first sidewall, the polarized light that has exited the first sidewall is configured to radiate in a predetermined direction, and the at least one reflector includes reflectors is arranged to specularly reflect the polarized light that has exited the second sidewall towards the predetermined direction.

In Example 27, the subject matter of Example 26 includes, wherein: the plurality of sidewalls further includes a third sidewall and a fourth sidewall opposing the third sidewall, the first sidewall and the second sidewall arranged substantially perpendicular to the third sidewall and the fourth sidewall, and the at least one reflector includes reflectors arranged to specularly reflect the polarized light that has exited the third sidewall and the fourth sidewall towards the predetermined direction.

In Example 28, the subject matter of Examples 19-27 includes, wherein: forming the LED chip comprises forming the semiconductor stack to have a plurality of fins extending from a substrate, each fin contains the n-type semiconductor, the p-type semiconductor, and the active region, and light that is to be generated by the active region in each fin is configured to exit a top surface of the fin as the polarized light.

In Example 29, the subject matter of Example 28 includes, wherein forming the LED chip comprises isolating the plurality of fins from each other.

In Example 30, the subject matter of Examples 28-29 includes, wherein forming the LED chip comprises: physically coupling the plurality of fins at one end, and providing a bond pad on a top of the one end to make electrical contact to the n-type semiconductor.

In Example 31, the subject matter of Examples 19-30 includes, wherein: forming the LED chip comprises forming the semiconductor stack to have a plurality of fins extending from an underlying structure, the underlying structure includes the p-type semiconductor, the active region, and a portion of the n-type semiconductor, each fin contains a remaining portion of the n-type semiconductor, and light generated by the active region is configured to exit a top surface of the fin as polarized light.

In Example 32, the subject matter of Example 31 includes, wherein: forming the LED chip comprises covering the portion of the n-type semiconductor other than locations from which the fins extend using a reflective material, and the reflective material is configured to reflect light of a wavelength of the light generated by the active region, the reflective material comprising at least one material selected from a metal and a multilayer structure.

Example 33 is at least one machine-readable medium including instructions that, when executed by processing circuitry, cause the processing circuitry to perform operations to implement of any of Examples 1-32.

Example 34 is an apparatus comprising means to implement of any of Examples 1-32.

Example 35 is a system to implement of any of Examples 1-32.

Example 36 is a method to implement of any of Examples 1-32.

While only certain features of the system and method have been illustrated and described herein, many modifications and changes will occur to those skilled in the art. It is, therefore, to be understood that the appended claims are intended to cover all such modifications and changes. Method operations may be performed substantially simultaneously or in a different order.

Although an embodiment has been described with reference to specific example embodiments, it will be evident that various modifications and changes may be made to these embodiments without departing from the broader scope of the present disclosure. Accordingly, the specification and drawings are to be regarded in an illustrative rather than a restrictive sense. The accompanying drawings that form a part hereof show, by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

The subject matter may be referred to herein, individually and/or collectively, by the term “embodiment” merely for convenience and without intending to voluntarily limit the scope of this application to any single inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, UE, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects. As indicated herein, although the term “a” is used herein, one or more of the associated elements may be used in different embodiments. For example, the term “a processor” configured to carry out specific operations includes both a single processor configured to carry out all of the operations as well as multiple processors individually configured to carry out some or all of the operations (which may overlap) such that the combination of processors carry out all of the operations. Further, the term “includes” may be considered to be interpreted as “includes at least” the elements that follow.

The Abstract of the Disclosure is submitted with the understanding that it will not be used to interpret or limit the scope or meaning of the claims. In addition, in the foregoing Detailed Description, it may be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

1. A light-emitting diode (LED) structure comprising:
an LED chip comprising a semiconductor stack that includes an n-type semiconductor, a p-type semiconductor, and an active region sandwiched between the n-type semiconductor and the p-type semiconductor, the semiconductor stack having an exit surface from which light generated by the active region is to be waveguided to exit the semiconductor stack as polarized light; and
a submount to which the LED chip is electrically coupled.

2. The LED structure of claim 1, wherein the LED chip has a shape configured to enlarge an area of the exit surface and reduce internal light absorption.

3. The LED structure of claim 1, wherein the LED chip has a shape configured to increase internal reflection to enhance light emission efficiency from the exit surface.

4. The LED structure of claim 1, wherein the LED chip further comprises reflective material disposed on at least one surface other than the exit surface, the reflective material configured to reflect light of a wavelength of the light generated by the active region, the reflective material comprising at least one material selected from a metal and a multilayer structure.

5. The LED structure of claim 1, wherein:
the semiconductor stack has a plurality of sidewalls from which light generated by the active region is configured to exit the semiconductor stack as polarized light, and
the LED structure further comprises at least one reflector configured to specularly reflect the polarized light that has exited the semiconductor stack from at least one of the sidewalls.

6. The LED structure of claim 5, wherein:
the plurality of sidewalls includes a first sidewall and a second sidewall opposing the first sidewall, and
the at least one reflector includes a first reflector configured to specularly reflect the polarized light that has exited the first sidewall towards a predetermined direction and a second reflector configured to specularly reflect the polarized light that has exited the second sidewall towards the predetermined direction.

7. The LED structure of claim 6, wherein the predetermined direction is substantially parallel to surfaces of the opposing sidewalls.

8. The LED structure of claim 5, wherein:
the plurality of sidewalls includes a first sidewall and a second sidewall opposing the first sidewall,
the polarized light that has exited the first sidewall is configured to radiate in a predetermined direction, and
the at least one reflector includes reflectors configured to specularly reflect the polarized light that has exited the second sidewall towards the predetermined direction.

9. The LED structure of claim 8, wherein:
the plurality of sidewalls further includes a third sidewall and a fourth sidewall opposing the third sidewall, the first sidewall and the second sidewall arranged substantially perpendicular to the third sidewall and the fourth sidewall, and
the at least one reflector includes reflectors configured to specularly reflect the polarized light that has exited the third sidewall and the fourth sidewall towards the predetermined direction.

10. The LED structure of claim 1, wherein:
the LED chip comprises a first portion in which light is to be generated and a second portion in which light is not to be generated, the second portion is laterally adjacent to and substantially planar with the first portion, and
a contact pad is disposed on the first portion, the contact pad is electrically coupled with the n-type semiconductor and having dimensions for a wirebond contact.

11. The LED structure of claim 1, wherein:
the LED chip comprises a first portion in which light is to be generated and a second portion in which light is not to be generated, the second portion is laterally adjacent to the first portion, the second portion being etched to the p-type semiconductor,
a first contact pad is disposed on the first portion, the first contact pad is electrically coupled with the n-type semiconductor and having dimensions sufficient for a first wirebond contact, and
a second contact pad is disposed on the second portion, the second contact pad is electrically coupled with the p-type semiconductor and having dimensions sufficient for a second wirebond contact.

12. The LED structure of claim 1, wherein:
the semiconductor stack comprises a plurality of fins extending from a substrate,
each fin contains the n-type semiconductor, the p-type semiconductor, and the active region, and
light that is to be generated by the active region in each fin is configured to exit a top surface of the fin as the polarized light.

13. The LED structure of claim 12, wherein each of the plurality of fins is isolated from one another.

14. The LED structure of claim 12, wherein:
each of the plurality of fins is physically connected at one end, and
a bond pad is disposed on a top of the one end to make electrical contact to the n-type semiconductor.

15. The LED structure of claim 1, wherein:
the semiconductor stack comprises a plurality of fins extending from an underlying structure,
the underlying structure includes the p-type semiconductor, the active region, and a portion of the n-type semiconductor,
each fin contains a remaining portion of the n-type semiconductor, and
light generated by the active region is configured to exit a top surface of the fin as polarized light.

16. The LED structure of claim 15, wherein:
the underlying structure further includes reflective material covering the portion of the n-type semiconductor other than locations from which the fins extend, and
the reflective material is configured to reflect light of a wavelength of the light generated by the active region, the reflective material comprising at least one material selected from a metal and a multilayer structure.

17. An illumination device comprising:
a light-emitting diode (LED) chip comprising a sidewall from which light generated by an active semiconductor region is waveguided to exit the LED chip as polarized light; and
a submount to which the LED chip is electrically coupled, the submount comprising control circuitry to control light emission from the LED chip.

18. The illumination device of claim 17, wherein:
the LED chip has a plurality of sidewalls from which light generated by the active semiconductor region is configured to exit the LED chip as polarized light, and
the illumination device further comprises at least one reflector configured to specularly reflect the polarized light that has exited the LED chip from at least one of the sidewalls.

19. A method of fabricating an illumination device, the method comprising:
epitaxially growing, on a substrate, a semiconductor stack that includes an n-type semiconductor, a p-type semiconductor, and an active region sandwiched between the n-type semiconductor and the p-type semiconductor;
forming a light-emitting diode (LED) chip having an exit surface from which light generated by the active region is waveguided to exit the semiconductor stack as polarized light; and
electrically coupling the LED chip to a submount to control light emission from the LED chip.

20. The method of claim 19, wherein forming the LED chip comprises at least one of:
shaping the LED chip to have a first shape configured to enlarge an area of the exit surface and reduce internal light absorption,
shaping the LED chip to have a second shape configured to increase internal reflection to enhance light emission efficiency from the exit surface, or
arranging reflective material disposed on at least one surface other than the exit surface, the reflective material arranged to reflect light of a wavelength of the light generated by the active region, the reflective material comprising at least one material selected from a metal and a multilayer structure.
